(19) United States
(12) Patent Application Publication
(10) Pub. No.: US 2026/0152963 A1
(43) Pub. Date: Jun. 4, 2026

(54) MODULAR COMMON POLE

(71) Applicant: DARWIN PRECISIONS CORPORATION, Hsinchu County (TW)

(72) Inventor: HSUAN YAO, Hsinchu County (TW)

(21) Appl. No.: 19/004,501

(22) Filed: Dec. 30, 2024

(30) Foreign Application Priority Data
Dec. 4, 2024 (TW) 113147050

(51) Int. Cl. E04H 12/18; E04H 12/00

(52) U.S. Cl. CPC E04H 12/18; E04H 12/003

(57) ABSTRACT

A modular common pole includes a main-pole structure and a chassis. The main-pole structure includes a main-pole body and a main-pole appearance module. The main-pole body includes a first main-pole portion and a second main-pole portion, and the second main-pole portion is longitudinally connected to the first main-pole portion. The main-pole appearance parts are hung on the main-pole body. The chassis includes a chassis shell, a chassis door and chassis exterior parts. The chassis shell has a top surface, a bottom surface and a body surface. The chassis door is set on one side of the body surface. The body surface is connected to the opposite top surface and the bottom surface and forms an accommodation space. The second main-pole portion is longitudinally inserted into the chassis connection opening on the top surface. The chassis appearance parts are hung on the body surface of the chassis.

### FIELD OF THE INVENTION

The present invention belongs to a roadside common pole, and in particular to a modular common pole.

### BACKGROUND OF THE INVENTION

Generally speaking, street lamps, street nameplates, traffic lights and traffic signs alongside urban roads may be managed by different government departments respectively. Due to the lack of unified management, there may be a variety of poles erected alongside the road. Moreover, temporary billboards are often set up alongside the road, or various types of advertising leaflets are arbitrarily attached to the poles. This will lead to a messy city landscape.

In order to solve above problem, the street lamp, the street nameplate, the traffic light, the traffic sign and the advertisement can be integrated in one pole, which is called a common pole structure.

### SUMMARY OF THE INVENTION

The present invention provides a modular common pole. Modular design is used to improve the assembly efficiency and aesthetic appearance so as to improve the use efficiency of the common pole. The modular common pole has the functions of waterproofing, drainage and heat dissipation.

In order to achieve one or some or all of the above objectives or other objectives, an embodiment of the present invention provides a modular common pole, including a main-pole structure and a chassis. The main-pole structure includes a main-pole body and a main-pole appearance module. The main-pole body includes a first main-pole portion and a second main-pole portion. The first main-pole portion has a first top end and a first bottom end that are opposite. The second main-pole portion has a second top end and a second bottom end that are opposite. The second top end is connected to the first bottom end such that the second main-pole portion is longitudinally connected to the first main-pole portion. The main-pole appearance module includes a plurality of main-pole appearance parts. The main-pole appearance parts are hung on the main-pole body. The chassis includes a chassis shell and a chassis appearance part. The chassis shell has a top surface, a bottom surface and a body surface. The top surface and the bottom surface are opposite. The body surface is connected to the top surface and the bottom surface and forms an accommodation space. The second main-pole portion is longitudinally inserted into the top surface of the chassis shell with the second bottom end located in the accommodation space. The chassis appearance part is hung on the body surface of the chassis shell.

In an embodiment of the present invention, the chassis further includes a chassis door. The chassis door is arranged on one side of the body surface. The top surface of the chassis is provided with a chassis connection opening, and the second main-pole portion is longitudinally inserted into the chassis shell through the chassis connection opening.

In an embodiment of the present invention, an inside of the main-pole body has at least one conduit channel running through the first bottom end, the second top end and the second bottom end and communicating with the accommodation space of the chassis. At least one conduit via communicating with the at least one conduit channel is formed in a side wall of the first main-pole portion and/or a side wall of the second main-pole portion.

In an embodiment of the present invention, the modular common pole further includes at least one waterproof component. The at least one waterproof component includes a waterproof plate and a waterproof connector. The waterproof plate is arranged on the main-pole body and corresponds to the conduit via, and the waterproof connector runs through the waterproof plate and the conduit via.

In an embodiment of the present invention, the main-pole body further includes a support structure arranged around the second bottom end and located in the accommodation space, and the support structure is further connected to the top surface of the chassis shell.

In an embodiment of the present invention, each of the main-pole appearance parts has a decorative plate, two connecting plates and two mounting plates. The main-pole body includes a plurality of snap-fit members. The two connecting plates are arranged on two opposite sides of the decorative plate, and the two mounting plates are respectively connected to the two connecting plates and arranged on an inner side of the decorative plate. Each of the main-pole appearance parts is provided with a plurality of snap-fit slots and a plurality of mounting openings. The snap-fit slots are provided in the connecting plates and the mounting plates. The snap-fit members are respectively inserted into the corresponding snap-fit slots such that the main-pole appearance parts are hung on the main-pole body. Each of the mounting openings is at least provided in the decorative plate and corresponds to the snap-fit slots.

In an embodiment of the present invention, the modular common pole further includes component fixing bars. The component fixing bars are longitudinally arranged on the main-pole structure. An elongated slot longitudinally extends on the component fixing bar. The elongated slot is suitable for an arrangement of light bars.

In an embodiment of the present invention, the modular common pole further includes a top device. The top device is arranged on the first top end, and the top device is an electronic device base or a cover.

In an embodiment of the present invention, the modular common pole further includes a plurality of fixing members. The main-pole body has a plurality of fixing holes, and the fixing members are suitable to be locked to the fixing holes.

In an embodiment of the present invention, the modular common pole further includes an external device. At least part of the main-pole appearance parts have at least one through opening. The external device includes an external plate and an external rod. The external plate is detachably fixed to the main-pole body through part of the fixing members. One end of the at least one external rod is connected to the external plate. The external rod extends away from the main-pole body. The external rod runs out through the through opening. The other end of the external rod is suitable to be connected to an external electronic device.

In an embodiment of the present invention, the modular common pole further includes an auxiliary plate. The auxiliary plate is detachably fixed to the main-pole body through at least part of the fixing members.

In an embodiment of the present invention, the modular common pole further includes a platform. The platform is arranged at a joint of the second main-pole portion and the chassis shell. The platform includes a notch plate and a sealing plate. The notch plate and the sealing plate are suitable to be combined with each other to surround the second main-pole portion.

In an embodiment of the present invention, the chassis further includes at least one reinforcing plate. The at least one reinforcing plate is arranged in the accommodation space, and the at least one reinforcing plate is partially connected to the chassis shell.

In an embodiment of the present invention, the chassis further includes a water retaining slot, a drainage pipe, a laminated plate and a plurality of fixing bolts. The water retaining slot is arranged below the second bottom end. One end of the drainage pipe is connected to the water retaining slot. A part of the drainage pipe is arranged between the chassis shell and the reinforcing plate. The other end of the drainage pipe runs out of the chassis shell. The reinforcing plate is provided with a plurality of row holes. The fixing bolts are respectively inserted into the row holes. The laminated plate is movably arranged in the accommodation space through the fixing bolts.

In an embodiment of the present invention, the chassis further includes a fan. The fan is arranged in the accommodation space, and the body surface of the chassis shell is formed with a heat dissipation hole.

In an embodiment of the present invention, the modular common pole further includes a base. The base is arranged under the chassis.

According to the present invention, the main-pole structure and the chassis are detachable, so that the modular common pole can be easily assembled at a specific place. The modular common pole has the functions of waterproofing, drainage and heat dissipation. Each modular main-pole appearance part can be designed for advertisements separately, so the modular common pole of the present invention has higher use efficiency and helps to beautify the city landscape.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic three-dimensional view of a modular common pole according to an embodiment of the present invention;

FIG. 2 is a schematic exploded view of the modular common pole according to an embodiment of the present invention;

FIG. 3 is a schematic partial exploded view of a main-pole structure of the modular common pole according to an embodiment of the present invention;

FIG. 4 is a schematic partial perspective view of the main-pole structure of the modular common pole according to an embodiment of the present invention;

FIG. 5 is a schematic three-dimensional view of a chassis of the modular common pole according to an embodiment of the present invention;

FIG. 6 is a schematic application view of the chassis of the modular common pole according to an embodiment of the present invention;

FIG. 7 is a schematic sectional view of the chassis of the modular common pole according to an embodiment of the present invention;

FIG. 8 is a schematic bottom view of the chassis of the modular common pole according to an embodiment of the present invention;

FIG. 9 is a schematic partial exploded view of a main-pole body of the modular common pole according to an embodiment of the present invention;

FIG. 10 is a schematic three-dimensional application view of the modular common pole according to an embodiment of the present invention;

FIG. 11 is a schematic partial exploded application view of the main-pole body of the modular common pole according to an embodiment of the present invention; and

FIG. 12 is a schematic partial exploded application view of the main-pole body of the modular common pole according to an embodiment of the present invention.

### DETAILED DESCRIPTION OF PREFERRED EMBODIMENTS

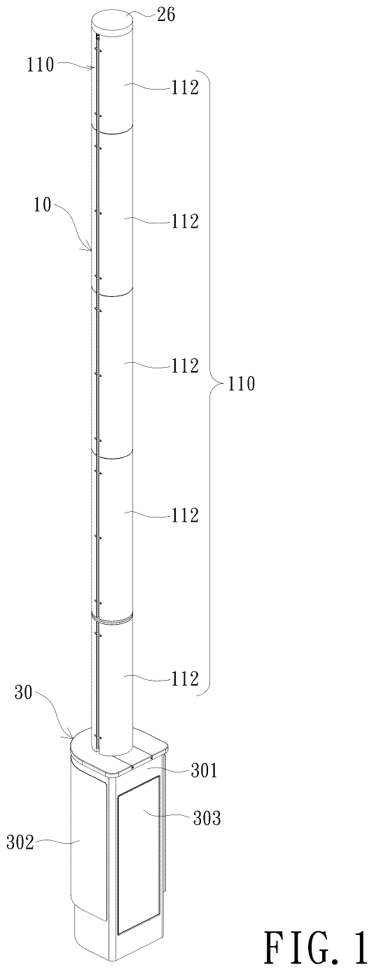

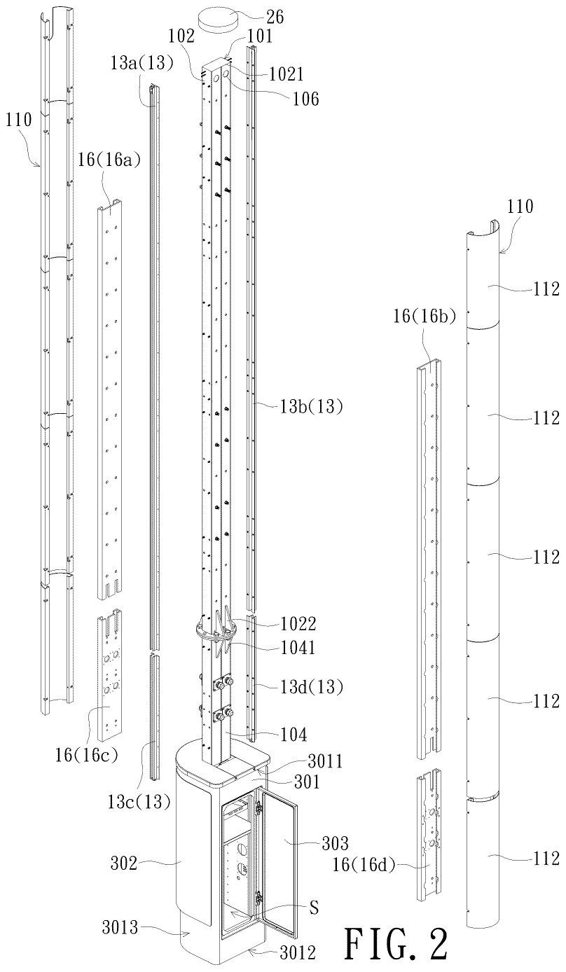

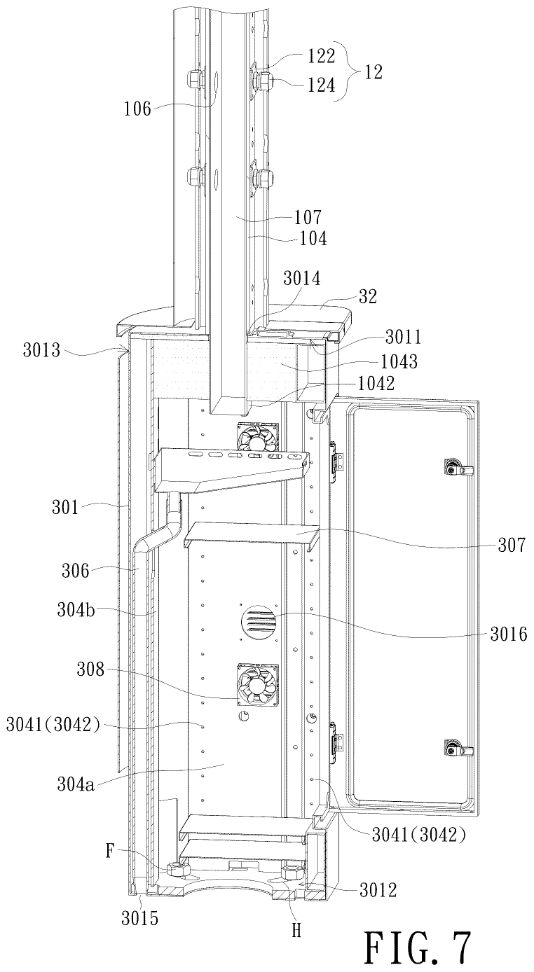

FIG. 1 is a schematic three-dimensional view of a modular common pole according to an embodiment of the present invention. FIG. 2 is a schematic exploded view of the modular common pole according to an embodiment of the present invention. As shown in FIG. 1 and FIG. 2, the modular common pole 1 includes a main-pole structure 10 and a chassis 30. The main-pole structure 10 includes a main-pole body 101 and a main-pole appearance module 110. The main-pole body 101 includes a first main-pole portion 102 and a second main-pole portion 104. The first main-pole portion 102 has a first top end 1021 and a first bottom end 1022 that are opposite. The second main-pole portion 104 has a second top end 1041 and a second bottom end 1042 (shown in FIG. 7 described later) that are opposite. The second top end 1041 is connected to the first bottom end 1022 such that the second main-pole portion 104 is longitudinally connected to the first main-pole portion 102. The main-pole appearance module 110 includes a plurality of main-pole appearance parts 112. The main-pole appearance parts 112 are hung on the main-pole body 101. The chassis 30 includes a chassis shell 301 and a chassis appearance part 302. The chassis shell 301 has a top surface 3011, a bottom surface 3012 and a body surface 3013. The top surface 3011 and the bottom surface 3012 are opposite. The body surface 3013 is connected to the top surface 3011 and the bottom surface 3012 and forms an accommodation space S. The second main-pole portion 104 is longitudinally inserted into the top surface 3011 of the chassis shell 301 with the second bottom end 1042 located in the accommodation space S. The chassis appearance part 302 is hung on the body surface 3013 of the chassis shell 301.

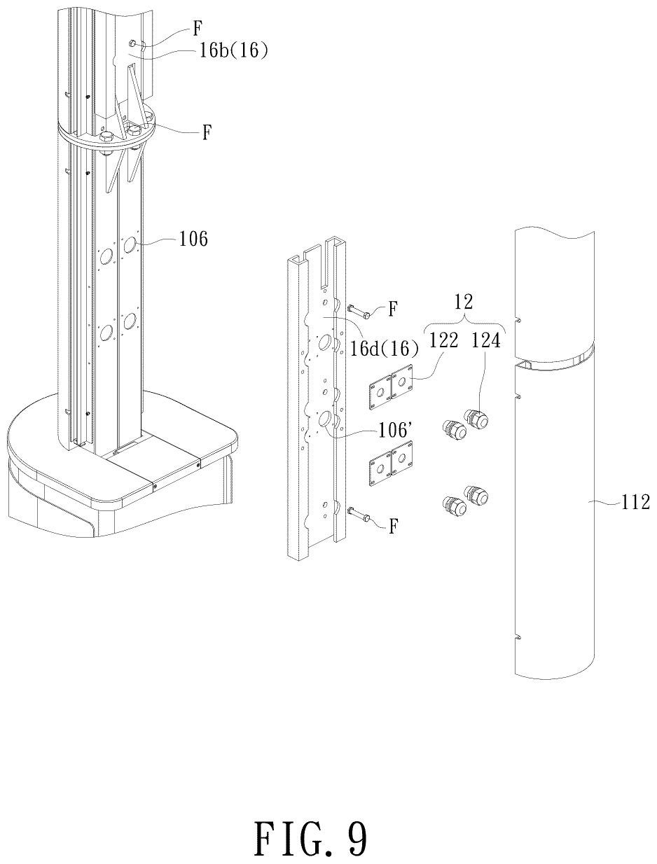

In an embodiment, the first main-pole portion 102 and the second main-pole portion 104 may be connected through fixing members F (shown in FIG. 9 described later) or through a mortise and tenon joint, but are not limited thereto. In an embodiment, the chassis 30 further includes a chassis door 303 arranged on one side of the body surface 3013. The top surface 3011 of the chassis 30 is provided with a chassis connection opening 3014 (shown in FIG. 7 described later), and the second main-pole portion 104 is longitudinally inserted into the chassis shell 301 through the chassis connection opening 3014.

As shown in FIG. 2, in an embodiment, the plurality of main-pole appearance parts 112 may be sequentially arranged from the first top end 1021 of the first main-pole portion 102 toward the chassis 30, and the plurality of main-pole appearance parts 112 are hung outside the main-pole body 101 in pairs with each pair of the main-pole appearance parts opposite to each other, but the present invention is not limited thereto. The main-pole appearance parts 112 may be hung only on the first main-pole portion 102, or only on the second main-pole portion 104, or on both the first main-pole portion 102 and the second main-pole portion 104.

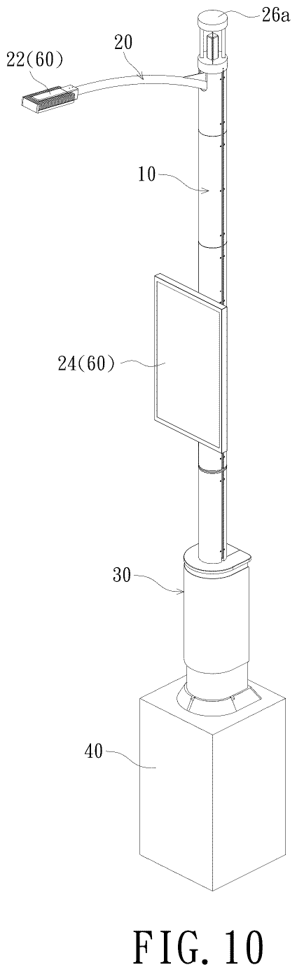

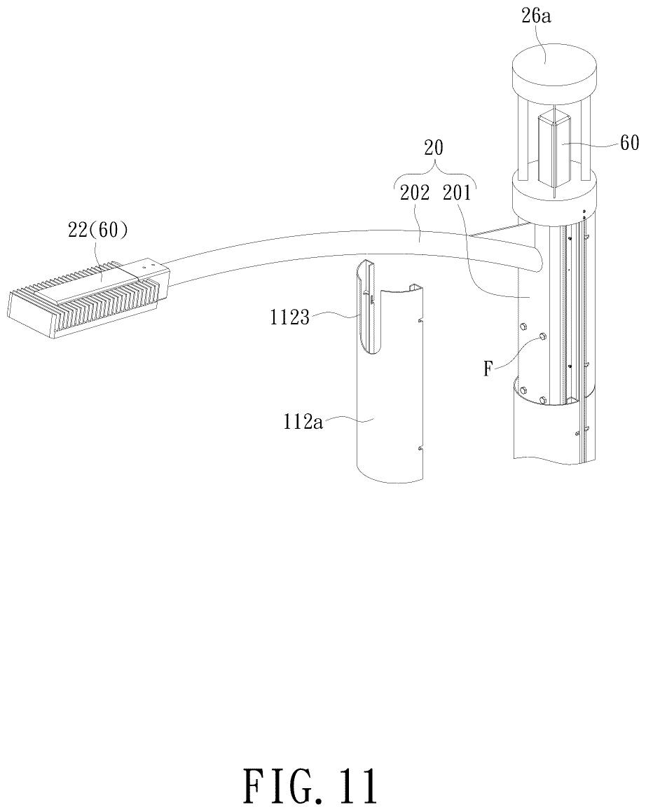

Furthermore, the modular common pole 1 further includes a top device 26. The top device 26 is arranged on the first top end 1021 and suitable for covering a top of the main-pole body 101. The top device 26 may be a cover, but is not limited thereto. The top device 26 may also be an electronic device base 26a (shown in FIG. 10 and FIG. 11 described later) for mounting an external electronic device 60 (shown in FIG. 11 described later).

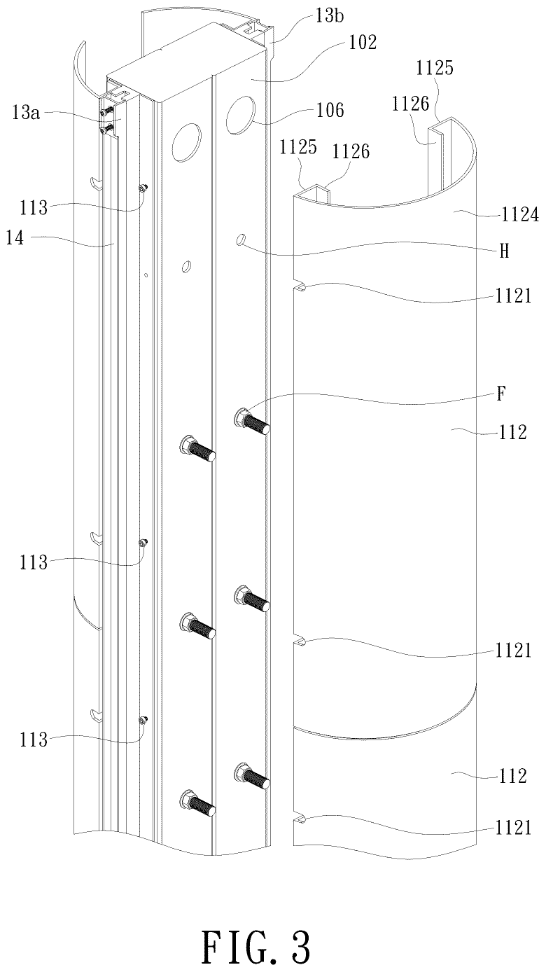

In an embodiment, the modular common pole 1 further includes component fixing bars 13. As shown in FIG. 2, in an embodiment where there are four component fixing bars 13, a component fixing bar 13a and a component fixing bar 13b are arranged oppositely on the first main-pole portion 102, and a component fixing bar 13c and a component fixing bar 13d are arranged oppositely on the second main-pole portion 104, but the present invention is not limited thereto. Each component fixing bar 13a, 13b, 13c, 13d is longitudinally formed with an elongated slot 14 (shown in FIG. 3) suitable for an arrangement of light bars (not shown). The number of the light bars may be less than, equal to or greater than the number of the component fixing bars 13. In an embodiment, the light bars may longitudinally extend from the component fixing bar 13a/13b of the first main-pole portion 102 to the component fixing bar 13c/13d of the second main-pole portion 104.

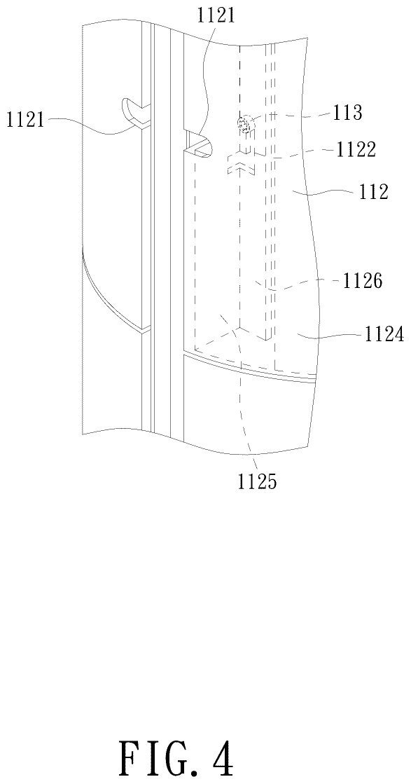

FIG. 3 is a schematic partial exploded view of the main-pole structure of the modular common pole according to an embodiment of the present invention. FIG. 4 is a schematic partial perspective view of the main-pole structure 10 of the modular common pole according to an embodiment of the present invention. As shown in FIG. 2 and FIG. 3, conduit vias 106 and a plurality of fixing holes H are formed in a side wall of the first main-pole portion 102 and/or a side wall of the second main-pole portion 104. The fixing holes H may be provided with the corresponding fixing members F according to needs. Through the combination of the fixing members F and the fixing holes H, auxiliary plates 16 (shown and illustrated in FIG. 9 described later) and/or an external device 20 (shown and illustrated in FIG. 10 and FIG. 11 described later) can be mounted to the main-pole body 101. When the main-pole appearance parts 112 are hung on the main-pole body 101, the main-pole appearance parts 112 can cover the conduit vias 106, the fixing holes H and the fixing members F.

As shown in FIG. 2, FIG. 3 and FIG. 4, the main-pole body 101 is longitudinally and sequentially provided with a plurality of snap-fit members 113 which are suitable for hanging the main-pole appearance parts 112. In an embodiment, the snap-fit members 113 and the conduit vias 106 may be arranged on different sides of the first main-pole portion 102 and/or the second main-pole portion 104, but the present invention is not limited thereto. Each of the main-pole appearance parts 112 has a decorative plate 1124, two connecting plates 1125 and two mounting plates 1126. The two connecting plates 1125 are arranged on two opposite sides of the decorative plate 1124, and the two mounting plates 1126 are respectively connected to the two connecting plates 1125 and arranged on an inner side of the decorative plate 1124. Each of the main-pole appearance parts 112 is provided with a plurality of mounting openings 1121 and a plurality of snap-fit slots 1122. The snap-fit slots 1122 are provided in the connecting plates 1125 and the mounting plates 1126. The snap-fit members 113 are inserted into the corresponding snap-fit slots 1122 such that the main-pole appearance parts 112 are hung on the main-pole body 101. Each of the mounting openings 1121 is at least provided in the decorative plate 1124 and corresponds to the snap-fit slots 1122, but the present invention is not limited thereto, so that the snap-fit members 113 combined with the snap-fit slots 1122 can be adjusted through the mounting openings 1121 during mounting. In an embodiment, in order to reinforce the main-pole appearance parts 112 to the main-pole body 101, auxiliary fixators (not shown) may be sleeved on the snap-fit members 113 through the mounting openings 1121, but the present invention is not limited thereto. For the convenience of mounting, the mounting openings 1121 may also be provided at the joint of the decorative plate 1124 and the connecting plate 1125. In an embodiment, part of the snap-fit slots 1122 may be hole-shaped instead.

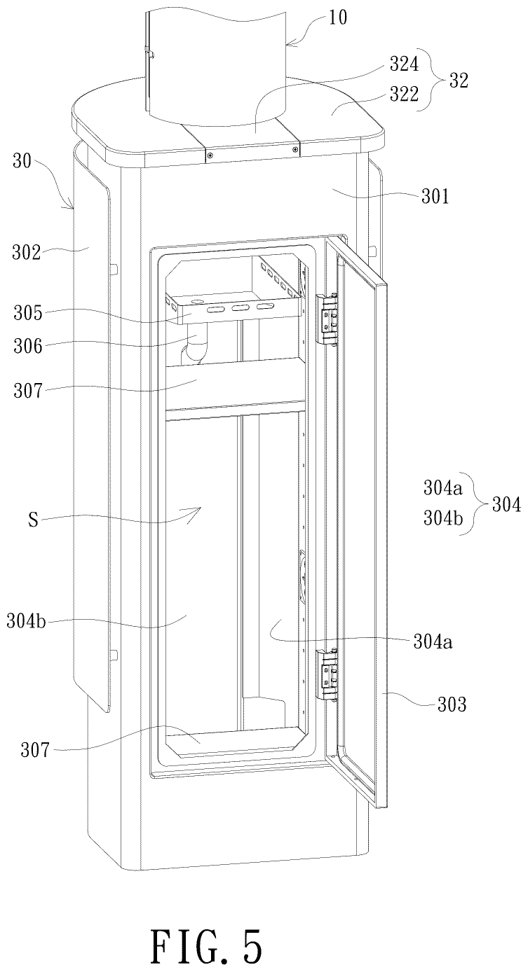

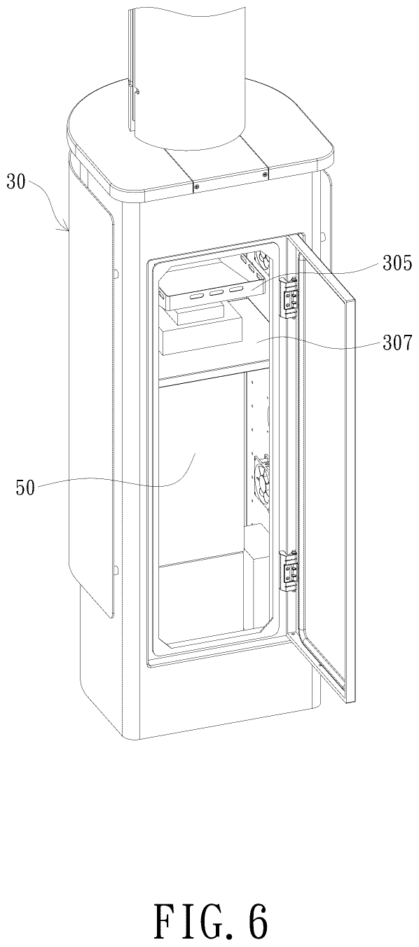

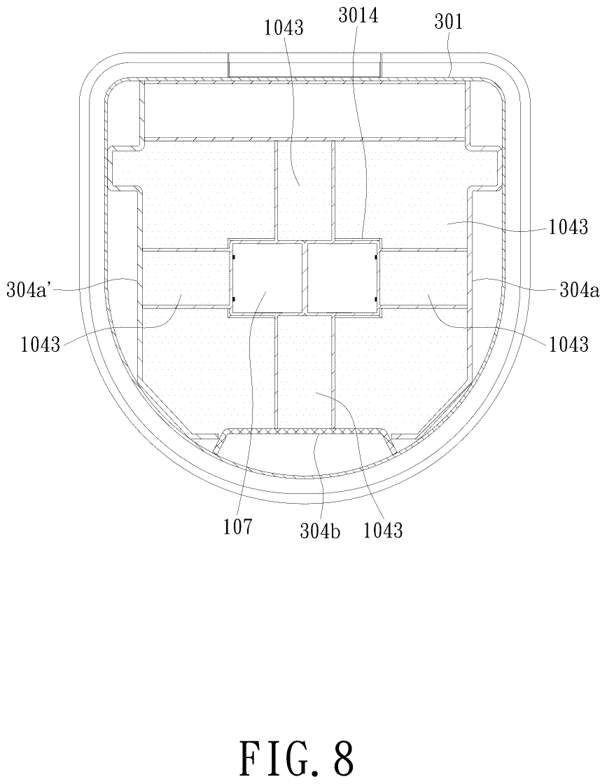

FIG. 5 is a schematic three-dimensional view of the chassis of the modular common pole according to an embodiment of the present invention. FIG. 6 is a schematic application view of the chassis of the modular common pole according to an embodiment of the present invention. FIG. 7 is a schematic sectional view of the chassis of the modular common pole according to an embodiment of the present invention. FIG. 8 is a schematic bottom view of the chassis of the modular common pole according to an embodiment of the present invention. As shown in FIG. 5, FIG. 6 and FIG. 8, the chassis 30 further includes at least one reinforcing plate 304. The reinforcing plate 304 is arranged in the accommodation space S and partially connected to the chassis shell 301. As shown in FIG. FIG. 8, for embodiment, there are three reinforcing plates 304. A reinforcing plate 304a and a reinforcing plate 304a′ are arranged oppositely, a reinforcing plate 304b is arranged between the reinforcing plate 304a and the reinforcing plate 304a′, and a part of the reinforcing plate 304a, 304a′, 304b is connected to an inner side of the body surface 3013 not provided with the chassis door 303. In an embodiment, the reinforcing plates 304 are welded to the chassis shell 301.

As shown in FIG. 5 to FIG. 7, the chassis 30 further includes a laminated plate 307 and fixing bolts 3042. The reinforcing plate 304a, 304a′ is provided with a plurality of row holes 3041, but the present invention is not limited thereto. The fixing bolts 3042 are respectively suitable to be inserted into the row holes 3041. The laminated plate 307 is movably arranged in the accommodation space S through the assembly of the fixing bolts 3042 and the row holes 3041. As shown in FIG. 6, in accordance with the application requirements of the modular common pole 1 (described later), the accommodation space S may be provided with an electronic device 50, such as, but not limited to, a controller, a computer mainframe, a battery and a router.

Furthermore, as shown in FIG. 7, the chassis 30 further includes a fan 308. The fan 308 is arranged in the accommodation space S and suitable for heat dissipation, such that air in the accommodation space S can be circulated, which prevents the electronic device 50 (shown in FIG. 6) from overheating due to operation. In an embodiment, the body surface 3013 of the chassis shell 301 is formed with a heat dissipation hole 3016, which is suitable for discharging heat generated by the operation of the electronic device 50 out of the chassis 30.

As shown in FIG. 5 to FIG. 7, the modular common pole 1 further includes a platform 32. The platform 32 is arranged at a joint of the second main-pole portion 104 of the main-pole structure 10 and the chassis shell 301. The platform 32 includes a notch plate 322 and a sealing plate 324. The notch plate 322 and the sealing plate 324 are suitable to be combined with each other to surround the second main-pole portion 104. The notch plate 322 and the sealing plate 324 that are combined are suitable for shielding or preventing foreign objects, such as, but not limited to, water and dust, from falling to the chassis 30 and affecting the operation of the electronic device 50 in the accommodation space S. During mounting, the notch plate 322 is arranged at the joint of the second main-pole portion 104 and the chassis shell 301 first, and then the sealing plate 324 and the notch plate 322 are combined to surround the second main-pole portion 104.

In an embodiment, the chassis 30 further includes a water retaining slot 305 a and drainage pipe 306. The water retaining slot 305 is arranged below the second bottom end 1042 of the second main-pole portion 104, and the water retaining slot 305 is suitable for receiving water drops falling from outside, so as to prevent the water drops from wetting the electronic device 50 in the accommodation space S. One end of the drainage pipe 306 is connected to the water retaining slot 305. A part of the drainage pipe 306 is arranged between the chassis shell 301 and the reinforcing plate 304. The other end of the drainage pipe 306 is connected to an opening 3015 of the chassis 30 and suitable for discharging the foreign objects, such as, but not limited to, water and dust, in the water retaining slot 305 out of the chassis. In an embodiment, the platform 32 is horizontal, but is not limited thereto. The platform 32 may be inclined outward to form an umbrella shape.

As shown in FIG. 7 and FIG. 8, the second main-pole portion 104 of the main-pole body 101 includes a support structure 1043 arranged around the second bottom end 1042 and located in the accommodation space S, and the support structure 1043 is further connected to the top surface 3011 of the chassis shell 301. In an embodiment, the support structure 1043 is flat and is welded to the top surface 3011, but the present invention is not limited thereto. The support structure 1043 further includes a cross structure. The cross structure is welded to the reinforcing plates 304a, 304a′, 304b and the chassis shell 301, such that the main-pole structure 10 is stably inserted into the chassis 30 and is less likely to fall over.

As shown in FIG. 7, an inside of the main-pole body 101 has conduit channels 107 running through the first bottom end 1022, the second top end 1041 and the second bottom end 1042 and communicating with the accommodation space S of the chassis 30. The conduit channels 107 communicate with the conduit vias 106 (marked in FIG. 2 and FIG. 3) provided in the first main-pole portion 102 and/or the second main-pole portion 104. In accordance with the application requirements of the modular common pole 1 (described later), the conduit vias 106 and the conduit channels 107 provide wiring spaces for conduits (not shown).

FIG. 9 is a schematic partial exploded view of the main-pole body of the modular common pole according to an embodiment of the present invention. As shown in FIG. 7 and FIG. 9, the modular common pole 1 further includes waterproof components 12. Each waterproof component 12 includes a waterproof plate 122 and a waterproof connector 124. The waterproof plate 122 is arranged on the main-pole body 101 and corresponds to the conduit via 106, and the waterproof connector 124 runs through the waterproof plate 122 and the conduit via 106. In accordance with the application requirements of the modular common pole 1 (described later), the conduit enters the conduit channel 107 through the conduit via 106 and leads to the accommodation space S of the chassis 30 so as to be connected to the electronic device 50 in the accommodation space S. The waterproof components 12 can prevent the foreign objects, such as, but not limited to, water and dust, in the conduits from entering the chassis 30 through the conduit channels 107 and affecting the operation of the electronic device 50 in the accommodation space S.

As shown in FIG. 2 and FIG. 9, the modular common pole 1 further includes at least one auxiliary plate 16, and the auxiliary plate 16 is detachably fixed to the main-pole body 101 through the fixing members F. As shown in FIG. 2 and FIG. 9, in an embodiment where there are four auxiliary plates 16, two of the auxiliary plates 16a, 16b are arranged oppositely on two sides of the first main-pole portion 102, and the other two auxiliary plates 16c, 16d are arranged oppositely on two sides of the second main-pole portion 104. Each auxiliary plate 16/16a/16b/16c/16d is provided with conduit vias 106′. During mounting, the conduit vias 106′ of the auxiliary plate 16/16a/16b/16c/16d correspond to the conduit vias 106 of the first main-pole portion 102 and/or the second main-pole portion 104. The waterproof plate 122 is arranged on the auxiliary plate 16/16a/16b/16c/16d and corresponds to the conduit via 106′, and the waterproof connector 124 runs through the waterproof plate 122 and the conduit vias 106, 106′.

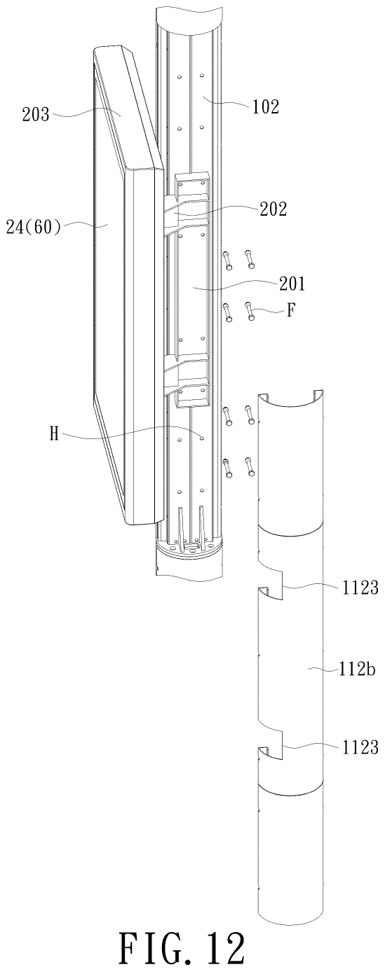

FIG. 10 is a schematic three-dimensional application view of the modular common pole according to an embodiment of the present invention. FIG. 11 is a schematic partial exploded application view of the main-pole body of the modular common pole according to an embodiment of the present invention. FIG. 12 is a schematic partial exploded application view of the main-pole body of the modular common pole according to an embodiment of the present invention. As shown in FIG. 10, the modular common pole 1 further includes a base 40. The base 40 is arranged under the chassis 30. As shown in FIG. 7 and FIG. 10, the bottom surface 3012 of the chassis 30 is provided with a plurality of fixing holes H, and the chassis 30 may be detachably fixed to the base 40 by making the fixing members F run through at least part of the fixing holes H.

As shown in FIG. 10, the modular common pole 1 further includes an external device 20 connected to the main-pole structure 10 so as to be connected to an external electronic device 60 or a billboard through the external device 20. In accordance with the application requirements of the modular common pole 1, different external electronic devices 60 or billboards may be selected. The external electronic device 60 may be, for embodiment, a lighting device 22, a display apparatus 24, a light bar, a monitor, a traffic light and/or an alarm. The billboard may be, for embodiment, an advertising board, a traffic sign and a street nameplate, but is not limited thereto. In an embodiment, when the top device 26 (shown in FIG. 1) is an electronic device base 26a, the external electronic device 60 may also be directly arranged on the electronic device base 26a, but the present invention is not limited thereto.

The external device 20 may have different structures according to different external electronic devices 60 to be connected. In an embodiment, as shown in FIG. 10 and FIG. 11, the external device 20 may include an external plate 201 and an external rod 202. The external plate 201 is detachably fixed to the main-pole body 101 through the fixing members F. The external rod 202 extends away from the main-pole body 101. One end of the external rod 202 is connected to the external plate 201, and the other end is suitable to be connected to the external electronic device 60. As shown in FIG. 11, when the external electronic device 60 is, for embodiment, a lighting device 22, the external plate 201 is connected to the first main-pole portion 102 through the fixing members F, one end of the external rod 202 is connected to the external plate 201, and the other end is suitable to be connected to the lighting device 22. In order to enable the external rod 202 to run through the main-pole appearance part 112 (shown in FIG. 1), the corresponding main-pole appearance part 112a has a through opening 1123. When the external rod 202 extends away from the main-pole body 101, the external rod 202 runs out through the through opening 1123.

In an embodiment, as shown in FIG. 12, when the external electronic device 60 is, for embodiment, a display device 24, the external device 20 includes an external plate 201, two external rods 202 and an external frame 203. The external plate 201 is connected to the first main-pole portion 102 through the fixing members F running through the fixing holes H. One end of each of the external rods 202 is connected to the external plate 201, and the other end is suitable to be connected to the external frame 203. The display device 24 is arranged on the external frame 203. In order to enable the two external rods 202 to run through the main-pole appearance part 112 (shown in FIG. 1), the corresponding main-pole appearance part 112b has two through openings 1123. The two external rods 202 respectively run out through the through openings 1123 and extend away from the main-pole body 101.

Furthermore, when the modular common pole 1 is provided with the external electronic device 60 according to application requirements, the external electronic device 60 may be connected to the electronic device 50 inside the chassis through the conduit. The conduit may enter the conduit channel 107 through the conduit via 106 and lead to the accommodation space S of the chassis 30, and be connected to the electronic device 50 in the accommodation space S. In an embodiment, a joint of the first bottom end 1022 and the second top end 1041 is provided with a junction opening. The conduit of the external electronic device 60 connected to the first main-pole portion 102 runs through the junction opening and runs into the conduit channel 107 through the conduit via 106 in the side wall of the second main-pole portion 104.

According to the present invention, the main-pole structure and the chassis are detachable, so that the modular common pole can be easily assembled at a specific place. The external device is designed corresponding to the main-pole structure, so that the external device can be detachably fixed to the main-pole structure. The modular common pole has the functions of waterproofing, drainage and heat dissipation. Each modular main-pole appearance part can be detached and designed for advertisements separately, or customized design can be made according to the external device, so that the modular common pole has higher use efficiency and helps to beautify the city landscape.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A modular common pole, comprising:
a main-pole structure, comprising:
a main-pole body, comprising a first main-pole portion and a second main-pole portion, the first main-pole portion having a first top end and a first bottom end that are opposite, the second main-pole portion having a second top end and a second bottom end that are opposite, and the second top end being connected to the first bottom end such that the second main-pole portion is longitudinally connected to the first main-pole portion; and
a main-pole appearance module, comprising a plurality of main-pole appearance parts, the main-pole appearance parts being hung on the main-pole body; and
a chassis, comprising a chassis shell and a chassis appearance part, the chassis shell having a top surface, a bottom surface and a body surface, the top surface and the bottom surface being opposite, the body surface being connected to the top surface and the bottom surface and forming an accommodation space, the second main-pole portion being longitudinally inserted into the top surface of the chassis shell with the second bottom end located in the accommodation space, and the chassis appearance part being hung on the body surface of the chassis shell.

2. The modular common pole according to claim 1, wherein the chassis further comprises a chassis door, the chassis door is arranged on one side of the body surface, the top surface of the chassis is provided with a chassis connection opening, and the second main-pole portion is longitudinally inserted into the chassis shell through the chassis connection opening.

3. The modular common pole according to claim 1, wherein an inside of the main-pole body has at least one conduit channel running through the first bottom end, the second top end and the second bottom end and communicating with the accommodation space of the chassis, wherein at least one conduit via communicating with the at least one conduit channel is formed in a side wall of the first main-pole portion and/or a side wall of the second main-pole portion.

4. The modular common pole according to claim 3, further comprising at least one waterproof component, wherein the at least one waterproof component comprises a waterproof plate and a waterproof connector, the waterproof plate is arranged on the main-pole body and corresponds to the at least one conduit via, and the waterproof connector runs through the waterproof plate and the at least one conduit via.

5. The modular common pole according to claim 1, wherein the main-pole body further comprises a support structure arranged around the second bottom end and located in the accommodation space, and the support structure is further connected to the top surface of the chassis shell.

6. The modular common pole according to claim 1, wherein each of the main-pole appearance parts has a decorative plate, two connecting plates and two mounting plates, the main-pole body comprises a plurality of snap-fit members, the two connecting plates are arranged on two opposite sides of the decorative plate, the two mounting plates are respectively connected to the two connecting plates and arranged on an inner side of the decorative plate, each of the main-pole appearance parts is provided with a plurality of snap-fit slots and a plurality of mounting openings, the snap-fit slots are provided in the connecting plates and the mounting plates, the snap-fit members are respectively inserted into the corresponding snap-fit slots such that the main-pole appearance parts are hung on the main-pole body, and each of the mounting openings is at least provided in the decorative plate and corresponds to the snap-fit slots.

7. The modular common pole according to claim 1, further comprising at least one component fixing bar, wherein the at least one component fixing bar is longitudinally arranged on the main-pole structure, an elongated slot longitudinally extends on the at least one component fixing bar, and the elongated slot is suitable for an arrangement of light bars.

8. The modular common pole according to claim 1, further comprising a top device, wherein the top device is arranged on the first top end, and the top device is an electronic device base or a cover.

9. The modular common pole according to claim 1, further comprising a plurality of fixing members, wherein the main-pole body has a plurality of fixing holes, and the fixing members are suitable to be locked to the fixing holes.

10. The modular common pole according to claim 9, further comprising at least one external device, wherein at least part of the main-pole appearance parts have at least one through opening, the at least one external device comprises an external plate and at least one external rod, the external plate is detachably fixed to the main-pole body through part of the fixing members, one end of the at least one external rod is connected to the external plate, the at least one external rod extends away from the main-pole body, the at least one external rod runs out through the at least one through opening, and the other end of the at least one external rod is suitable to be connected to an external electronic device.

11. The modular common pole according to claim 9, further comprising at least one auxiliary plate, wherein the at least one auxiliary plate is detachably fixed to the main-pole body through at least part of the fixing members.

12. The modular common pole according to claim 1, further comprising a platform, wherein the platform is arranged at a joint of the second main-pole portion and the chassis shell, the platform comprises a notch plate and a sealing plate, and the notch plate and the sealing plate are suitable to be combined with each other to surround the second main-pole portion.

13. The modular common pole according to claim 1, wherein the chassis further comprises at least one reinforcing plate, the reinforcing plate being arranged in the accommodation space, and the at least one reinforcing plate being partially connected to the chassis shell.

14. The modular common pole according to claim 13, wherein the chassis further comprises a water retaining slot, a drainage pipe, at least one laminated plate and a plurality of fixing bolts, the water retaining slot is arranged below the second bottom end, one end of the drainage pipe is connected to the water retaining slot, a part of the drainage pipe is arranged between the chassis shell and the at least one reinforcing plate, the other end of the drainage pipe runs out of the chassis shell, the at least one reinforcing plate is provided with a plurality of row holes, the fixing bolts are respectively inserted into the row holes, and the at least one laminated plate is movably arranged in the accommodation space through the fixing bolts.

15. The modular common pole according to claim 1, wherein the chassis further comprises at least one fan, the fan is arranged in the accommodation space, and the body surface of the chassis shell is formed with at least one heat dissipation hole.

16. The modular common pole according to claim 1, further comprising a base, wherein the base is arranged under the chassis.
